(19) United States
(12) Patent Application Publication
(10) Pub. No.: US 2026/0305432 A1
(43) Pub. Date: Oct. 1, 2026

(54) APPARATUS AND METHOD FOR WAFER BONDING

(71) Applicant: Tokyo Electron Limited, Tokyo (JP)

(72) Inventors: Christopher Lattin, Austin, TX (US); Christopher Michael Netzband, Albany, NY (US); Adam James Gildea, Albany, NY (US)

(21) Appl. No.: 19/096,992

(22) Filed: Apr. 1, 2025

(51) Int. Cl. H01L 23/00

(52) U.S. Cl. CPC H10W 72/011; H10W 72/0198; H10W 99/00; H10W 72/071; H10W 80/301; H10W 80/333

(57) ABSTRACT

An apparatus is provided for die-to-wafer bonding. The apparatus includes a channel plate configured to hold a wafer and create a locally protruding region on the wafer. The apparatus also includes a manifold having a plurality of passages and configured to be coupled to the channel plate. A first channel within the channel plate is configured to be aligned with a first passage within the manifold, where the first passage is configured to be coupled to a gas flow line. The apparatus further includes a second channel within the channel plate configured to be aligned with a second passage within the manifold, where the second passage is configured to be coupled to a vacuum line.

### TECHNICAL FIELD

The present disclosure relates generally an apparatus and method in semiconductor manufacturing, and, in particular embodiments, to an apparatus and method for wafer bonding process.

### BACKGROUND

Die-to-wafer (D2W) bonding process in semiconductor manufacturing is used to integrate individual dies onto a larger wafer substrate. A die refers to a small block of semiconductor material that contains the circuitry necessary for a specific electronic function. D2W bonding enables the combination of diverse semiconductor technologies within a single platform, essential for creating advanced multi-die assemblies and system-on-chip applications. Die-to-wafer bonding supports the development of heterogeneous integrations, where different types of semiconductor dies with different functionalities are combined to enhance device performance and efficiency. This process is widely applied in fabricating high-density electronic packages, including memory modules, microprocessors, and various miniaturized devices, meeting the growing demand for compact and powerful electronic solutions.

### SUMMARY

In accordance with one aspect of the present invention, an apparatus is provided for die-to-wafer bonding. The apparatus includes a channel plate configured to hold a wafer and create a locally protruding region on the wafer. A manifold comprising a plurality of passages is configured to be coupled to the channel plate. The apparatus further includes a first channel within the channel plate, the first channel configured to be aligned with a first passage within the manifold, wherein the first passage is configured to be coupled to a gas flow line. Additionally, the apparatus includes a second channel within the channel plate, the second channel configured to be aligned with a second passage within the manifold, wherein the second passage is configured to be coupled to a vacuum line.

In accordance with another aspect of the present invention, a method is provided for die-to-wafer bonding. The method includes placing a wafer over a channel plate, forming a gas pocket between the channel plate and the wafer to form a first locally protruding region on the wafer, placing a first die on the first locally protruding region on the wafer, and bonding the first die to the wafer at the first locally protruding region.

In accordance with yet another aspect of the present invention, a method is provided for die-to-wafer bonding. The method includes placing a wafer over a channel plate, the channel plate being coupled to a manifold comprising a plurality of passages, and aligning a first passage within the manifold to a first channel within the channel plate, wherein the first passage is coupled to a gas flow line. The method further includes supplying gas through the first passage and the first channel to form a gas pocket between the wafer and the channel plate, wherein the gas pocket deforms the wafer to form a locally protruding region, and bonding a first die to the wafer at the locally protruding region.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1E are schematic cross-sectional views of a die-to-wafer bonding process using a polymer film, in accordance with an embodiment;

FIGS. 2A-2E are schematic cross-sectional views of a die-to-wafer bonding process using a polymer film with through-holes, in accordance with an embodiment;

FIGS. 3A-3E are schematic cross-sectional views of a die-to-wafer bonding process without a polymer film, in accordance with an embodiment;

FIGS. 4A-4B are schematic cross-sectional views of a wafer singulation process following die-to-wafer bonding, in accordance with an embodiment;

FIGS. 5A-5D are schematic cross-sectional views of a wafer singulation process following a die stacking process, in accordance with an embodiment;

FIGS. 6A-6B are schematic bottom views of a manifold extending portion and channel plate arrangement, in accordance with an embodiment;

FIGS. 7A-7D are schematic views illustrating gas and vacuum distribution configurations within a manifold, in accordance with an embodiment;

FIG. 8 is a schematic cross-sectional view of a direct die bonding process from a carrier, in accordance with an embodiment; and

FIG. 9 is a schematic cross-sectional view of a simultaneous multiple die bonding process from a carrier, in accordance with an embodiment.

### DETAILED DESCRIPTION OF ILLUSTRATIVE EMBODIMENTS

During die-to-wafer (D2W) bonding processes, the center of the die is brought into contact with a carrier wafer and subsequent bond propagation is driven by Van der Waals interactions. The forces driving the propagation of this bond will cause the die to stretch, creating a scaling misalignment between the die and the carrier pattern after the bond is complete. To ensure that the initiation occurs at the center of the die it is flexed. This flexure increases the distance the bond wave travel across the die creating further scaling misalignment. Finally, this scaling effect becomes more pronounced in faster bonding processes due to increased attractive forces between the die and the wafer. The combined outcome of these features of the D2W process is that scaling accounts for a major proportion of total misalignment and subsequent device performance degradation. While wafer-to-wafer (W2W) bonding allows for corrections by flexing the lower wafer, D2W bonding currently lacks a comparable solution to address the scaling issue from the carrier wafer side.

In various embodiments, a local protruding system may form a gas pocket below the wafer that creates a locally protruding region on the wafer during a bonding process. The gas pocket enables the wafer to undergo local elastic deformation when pressure is applied, resulting in the locally protruding region. The locally protruding region can be aligned with a footprint of a die, allowing the wafer and die to experience comparable scaling during bonding. In one or more embodiments, the bonding process may allow for bonding with a flat die, initiating contact at the center and allowing controlled stretching to the proper width, potentially eliminating excess scaling caused by pre-shaped dies.

In various embodiments, the local protruding system may provide precise control over the shape of locally protruding region through coordinated distribution of gas pressure and vacuum. In various embodiments, different combinations of pressure zones and vacuum containment enable formation of complex protruding shapes tailored to specific die geometries. This shape control capability enhances bonding precision and accommodates various die configurations.

In one or more embodiments, the system may enable direct die transfer from a carrier to the wafer without conventional pick and place operations. This direct bonding approach may reduce handling steps, minimize alignment errors, and increase throughput by eliminating individual die picking and placement cycles. The carrier-based transfer system may further enable simultaneous bonding of multiple dies, where multiple locally protruding regions may form on the wafer to receive multiple dies transferred directly from the carrier in parallel. This parallel processing capability may improve production efficiency compared to sequential die bonding approaches.

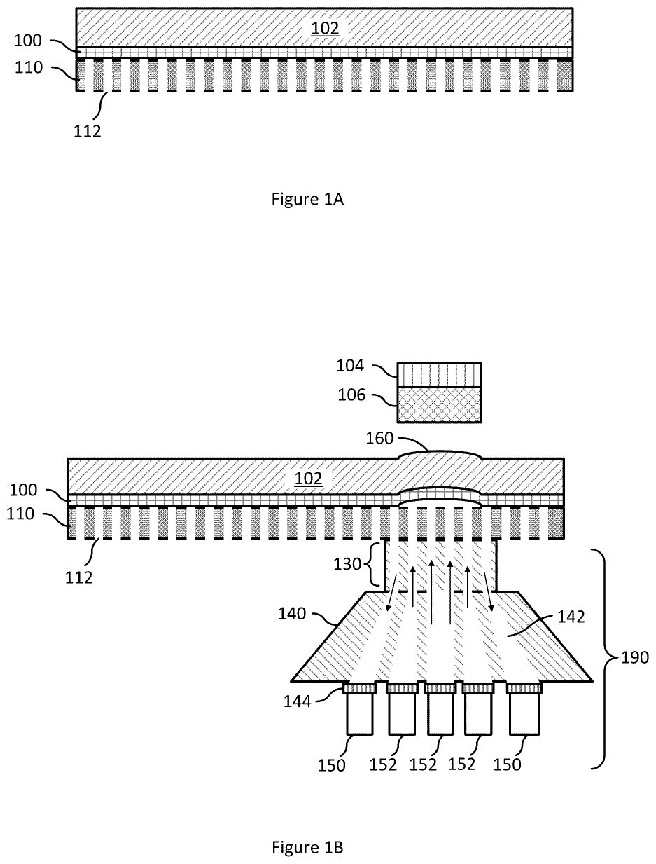

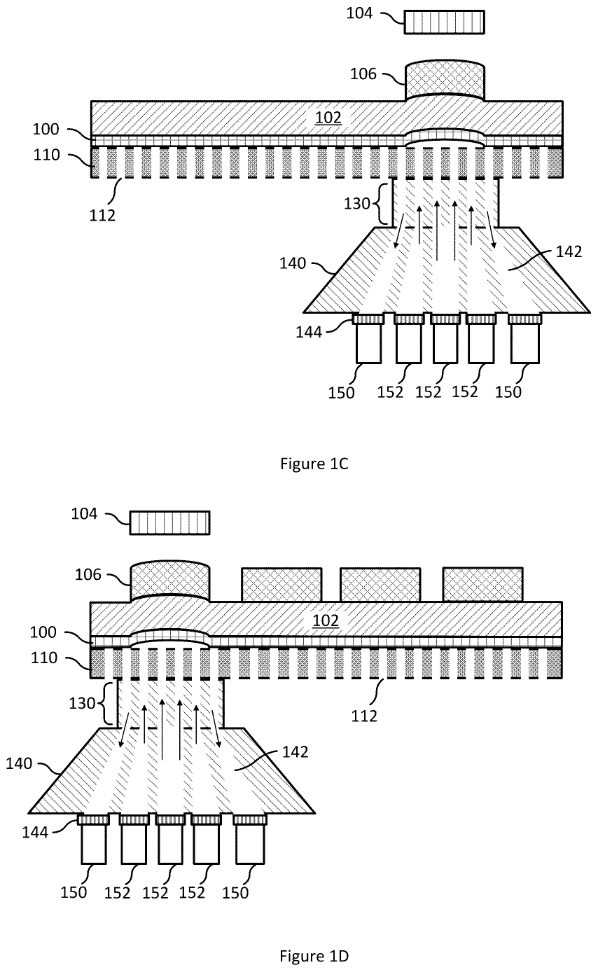

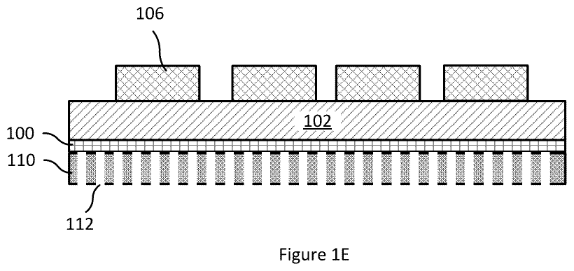

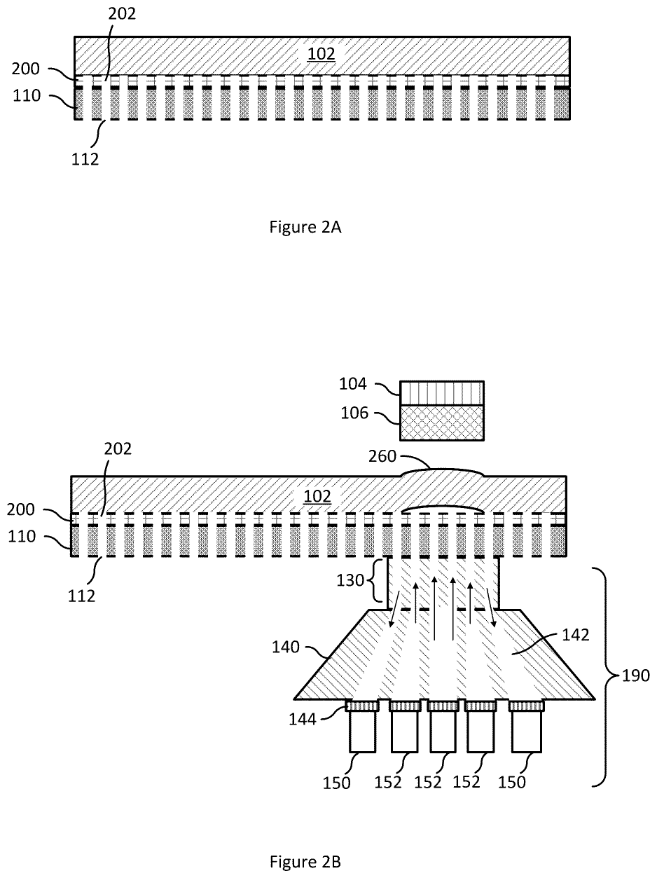

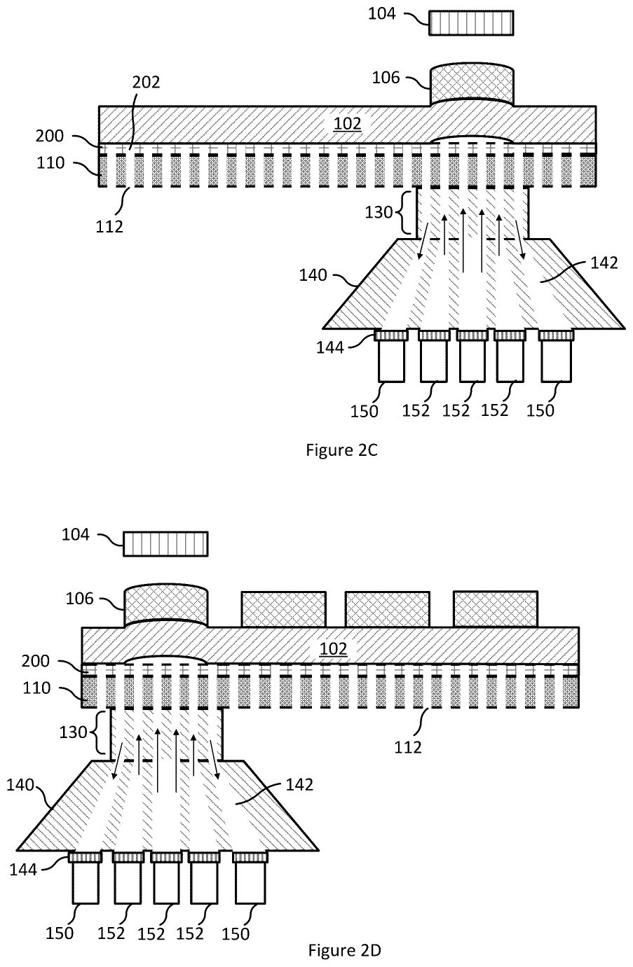

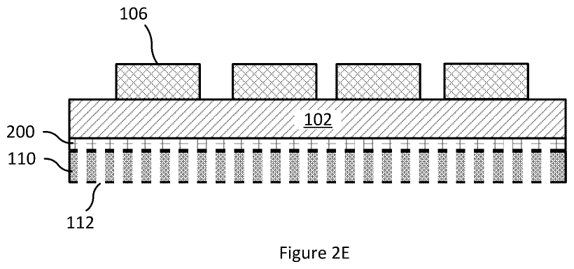

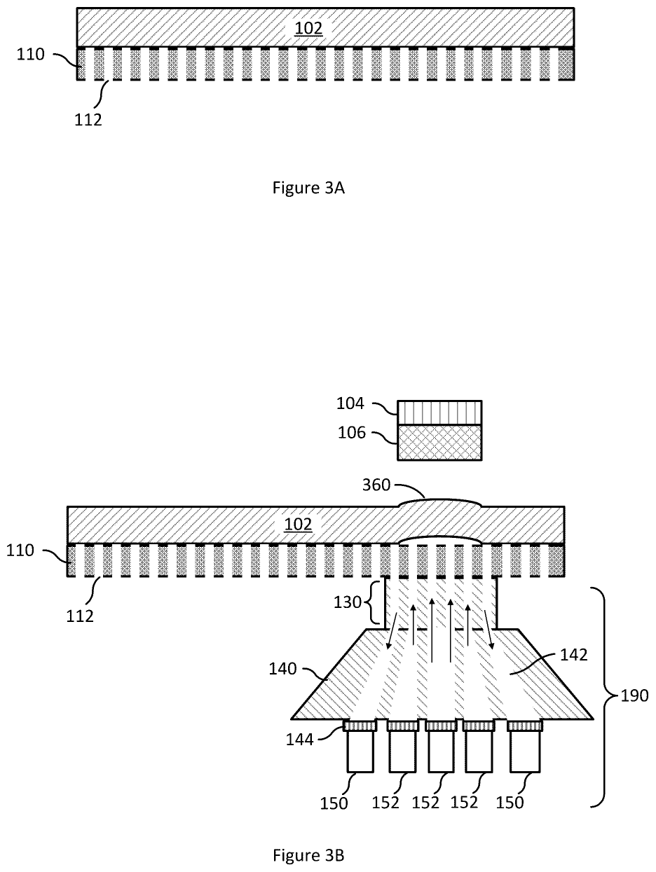

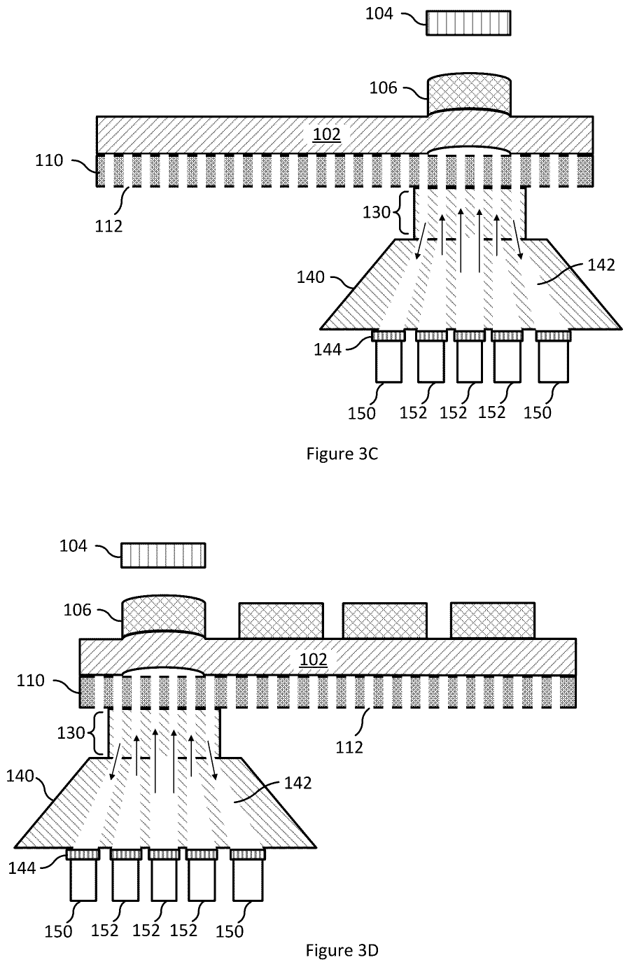

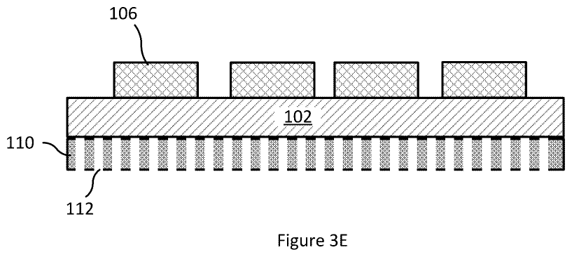

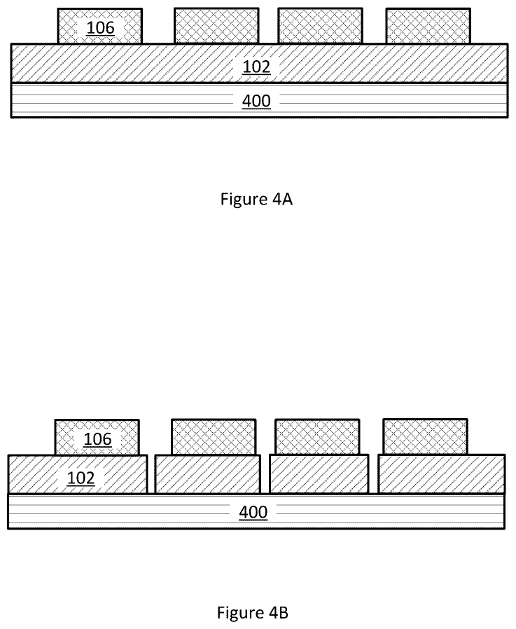

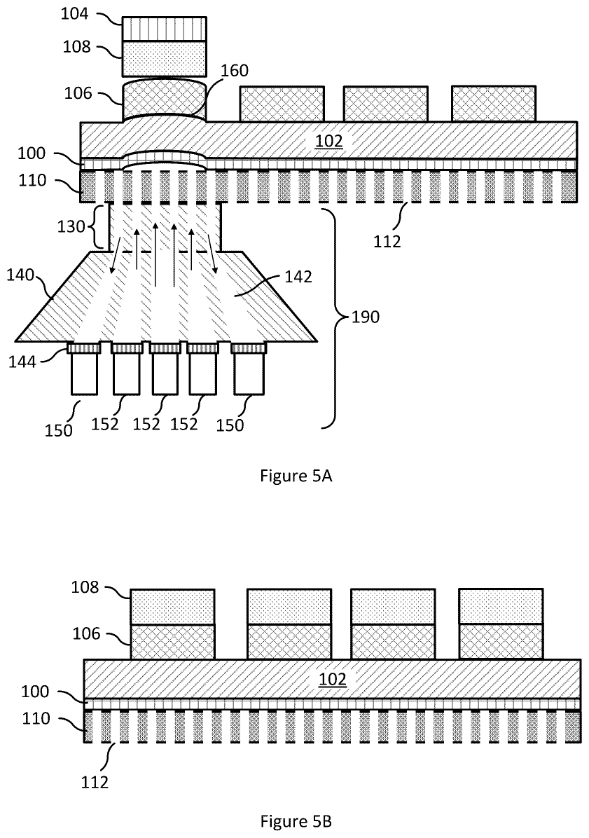

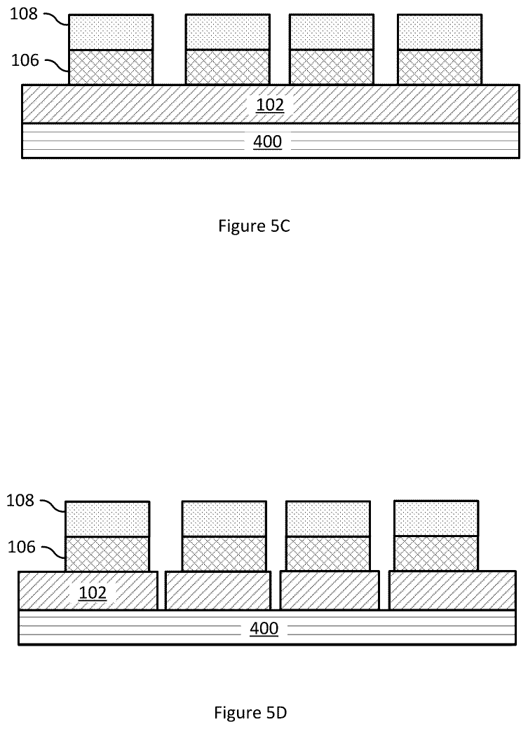

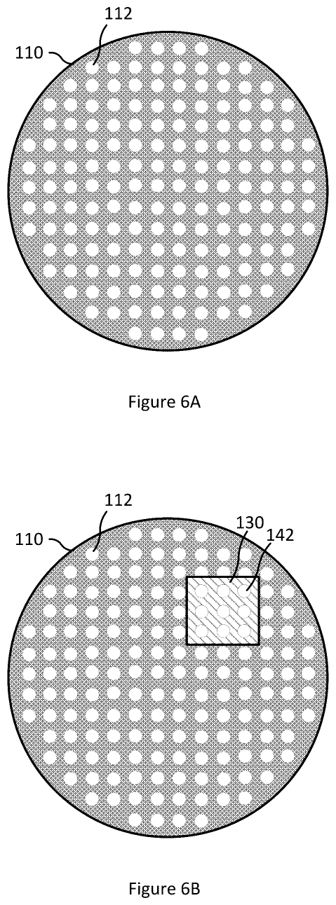

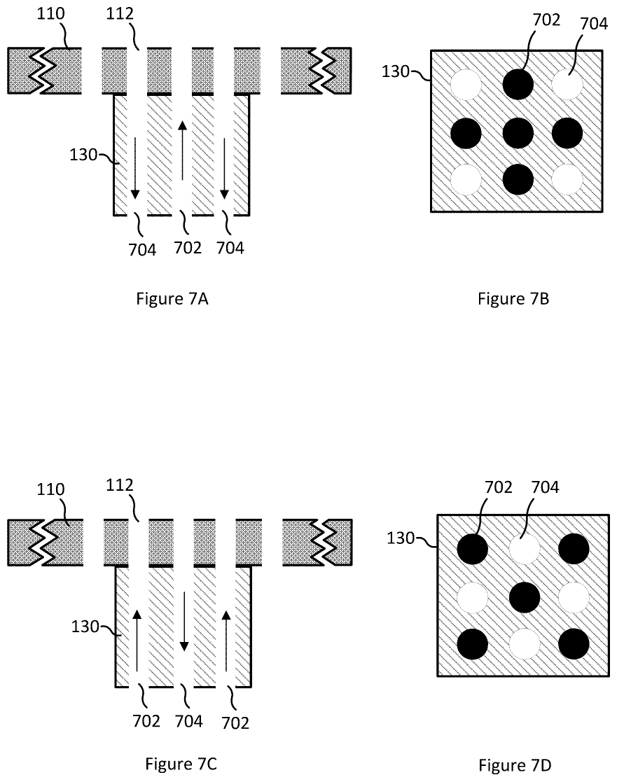

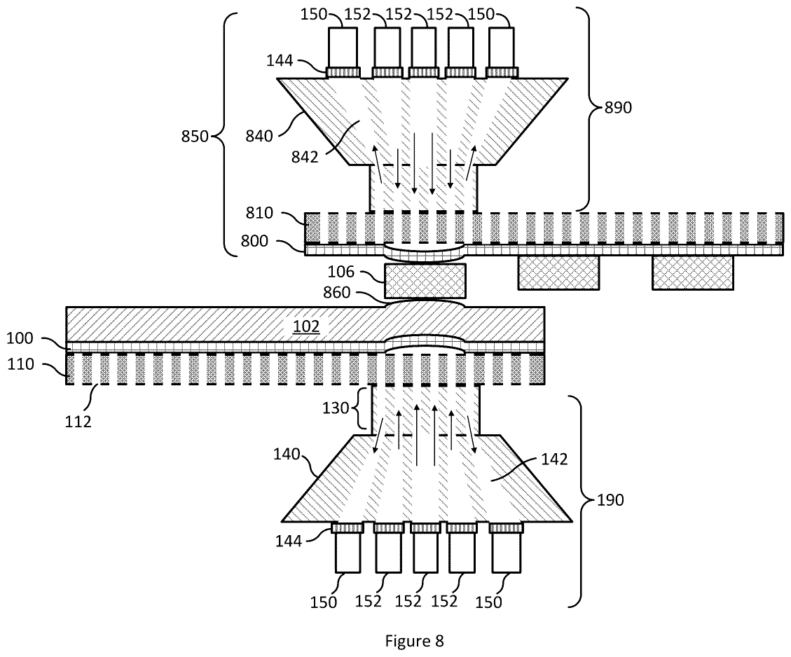

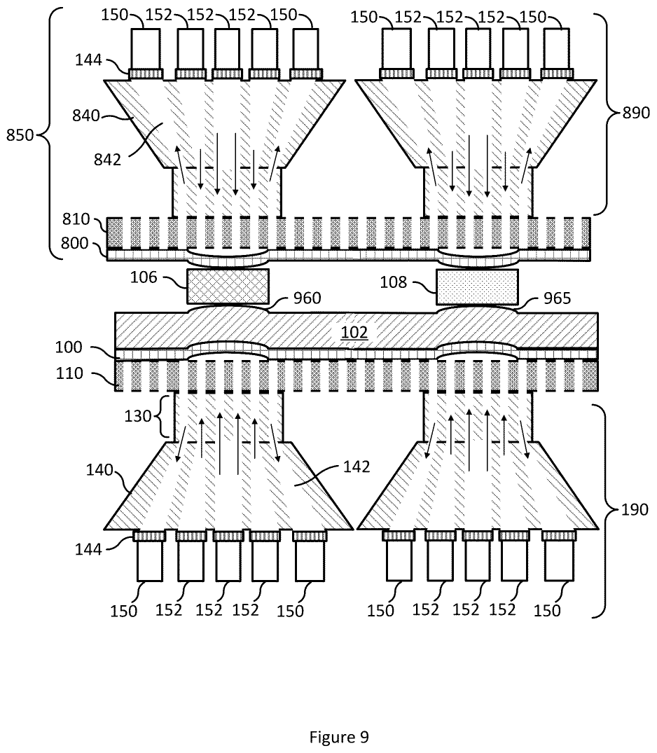

The figures illustrate various configurations and methods for die-to-wafer bonding utilizing gas pocket formation. FIGS. 1A-1E illustrate a die-to-wafer bonding process using a polymer film to hold the wafer. FIGS. 2A-2E illustrate an alternative die-to-wafer bonding process incorporating a polymer film with through-holes. FIGS. 3A-3E illustrate yet another die-to-wafer bonding process without a polymer film. FIGS. 4A-4B illustrate wafer singulation following die bonding. FIGS. 5A-5D demonstrate wafer singulation after stacking of additional dies. FIGS. 6A-6B illustrate a bottom view of a manifold extending portion and channel plate arrangement. FIGS. 7A-7D illustrate gas and vacuum distribution configurations within a manifold. FIG. 8 illustrates direct die bonding to the wafer from a carrier, and FIG. 9 illustrates simultaneous bonding of multiple dies from a carrier.

Example embodiments of the invention are described below. Other embodiments can also be understood from the entirety of the specification as well as the claims filed herein.

In accordance with an embodiment, FIGS. 1A-1E illustrate a die-to-wafer bonding process through locally protruding a wafer 102. The wafer 102 may be placed over a first side of a first polymer film 100, or referred to below as a polymer film 100, which comprises the first side and an opposite second side. In various embodiments, a first gas pocket, or referred to below as a gas pocket, adjacent to the opposite second side of the polymer film 100 may be formed to deform the polymer film 100 and form a first locally protruding region 160 on the wafer 102 as illustrated in FIG. 1B. The first locally protruding region 160 may be referred to below as the locally protruding region 160.

In FIG. 1A, the wafer 102 may be positioned on the polymer film 100. In various embodiments, the polymer film 100 may comprise polymer materials including polyimide, polydimethylsiloxane (PDMS), polytetrafluoroethylene (PTFE), polyethylene terephthalate (PET), polycarbonate, or the like. The polymer film 100 may generate van der Waals forces between its surface and the wafer 102, providing sufficient adhesion to hold the wafer 102 in position during processing.

The wafer 102 may be a blank silicon wafer, a silicon-on-insulator (SOI) wafer, a gallium arsenide wafer, a silicon carbide wafer, a quartz wafer, or any of various other semiconductor wafers. The wafer 102 may also be coated or layered with any number of additional materials, including compound semiconductors, various oxides, nitrides, carbides, metals, metal oxides, or metal nitrides.

In various embodiments, the polymer film 100 may be disposed over a channel plate 110. The channel plate 110 may comprise a plurality of channels 112 formed as through-holes that extend from a first surface to an opposite surface of the channel plate 110. The channels 112 may be distributed across the channel plate 110 to enable gas and vacuum delivery to selected regions below the polymer film 100. In various embodiments, the plurality of channels 112 may appear as an array of holes on the channel plate 110 from the top view illustrated in FIG. 6A. The channel plate 110 may be made from rigid materials comprising stainless steel, aluminum, Teflon quartz, titanium, ceramic materials such as alumina, zirconium oxide, silicon carbide, silicon nitride, high-strength polymers such as polyetherimide, aramid, polyethylene, PTFE, or the like. The channel plate 110 may resist deformation when exposed to vacuum or gas flow through the plurality of channels 112. The plurality of channels 112 may be through holes across the plate.

In various embodiments, the polymer film 100 may be secured to the channel plate 110 through distributed vacuum zones. The plurality of channels 112 across the channel plate 110, separate from those aligned with an extending portion 130 of a manifold 140, may be coupled to a vacuum source to create a consistent holding force. In some embodiments, these vacuum zones may form concentric rings or grid patterns around a perimeter of the channel plate 110, ensuring uniform contact between the polymer film 100 and the channel plate 110, or the wafer 102 and the channel plate 110 during the bonding process. In one or more embodiments, the vacuum level in these vacuum zones may be controlled to provide sufficient holding force without causing excessive deformation of the polymer film 100. In various embodiments, these vacuum zones may be independently controlled from the gas and vacuum distribution used for creating the locally protruding regions, enabling simultaneous polymer film holding and precise gas pocket formation.

In an alternative embodiment, the channel plate 110 may comprise an electrostatic chuck that holds the wafer 102 through electrostatic forces. In some embodiments, the electrostatic chuck may comprise a dielectric layer over conductive electrodes embedded within the body of the channel plate 110. When a voltage is applied to the electrodes, an electrostatic field may generate a clamping force that secures the wafer 102 to the channel plate 110. In some embodiments, the dielectric layer may comprise dielectric materials such as aluminum oxide, aluminum nitride, silicon dioxide, or the like.

In FIG. 1B, a local protruding system 190 may be configured to be coupled beneath the channel plate 110 through a manifold 140. The local protruding system 190 may be configured to create the locally protruding region 160 on the wafer 102. In one or more embodiments, the local protruding system 190 may comprise the manifold 140, vacuum lines 150 coupled to vacuum sources, and gas flow lines 152 coupled to gas sources. The vacuum lines 150 and gas flow lines 152 may be configured to be coupled to a plurality of passages in the manifold 140 through a plurality of connectors 144. In various embodiments, arrows in FIG. 1B may imply internal flow paths that direct gas and vacuum from the passages 142 through the extending portion 130.

In various embodiments, the connectors 144 may comprise standardized vacuum and gas fittings designed for semiconductor processing environments. The connectors 144 may comprise metal gasket face seal fittings, or flanges, to create leak-tight connections between external supply lines (e.g., vacuum lines 150 and gas flow lines 152) and the passages 142 of the manifold 140. Each connector 144 may incorporate metal gaskets, elastomeric seals, or copper gaskets rated for pressures ranging from vacuum to 100 psi operating conditions.

In one or more embodiments, the manifold 140 may comprise threaded ports or quick-connect receptacles machined directly into its body to accept the connectors 144. The connection interface incorporates safety features such as check valves or isolation valves to prevent backflow and enable independent control of each passage 142. The connectors 144 may comprise rotating collars or bayonet-style locking mechanisms for secure attachment while maintaining adjustability for routing external supply lines. In various embodiments, the connectors 144 may further include pressure monitoring ports or sensor integration points to verify connection status and monitor line pressure.

In various embodiments, the manifold 140 may comprise materials selected from aluminum, stainless steel, or other rigid materials compatible with semiconductor processing. The manifold 140 may comprise a plurality of passages 142 for distributing gas and vacuum through the channels 112 of the channel plate 110. In one or more embodiments, the manifold 140 may include an extending portion 130 configured to interface with the channel plate 110 through a sealing interface. The sealing interface may comprise elastomeric O-rings, gaskets, or precision-machined surfaces with surface roughness less than 1 micron to prevent gas or vacuum leakage between the passages 142 and the channels 112. The sealing interface prevents cross-contamination between gas and vacuum passages during operation. In an embodiment, the surface of the extending portion 130 facing the channel plate 110 may be coated with a layer of chemical-resistant material to enhance sealing properties and prevent surface degradation. Adjustable mounting mechanisms, such as leveling screws or kinematic mounts, may enable fine alignment adjustment to achieve uniform contact pressure across the sealing interface.

In various embodiments, the manifold 140 may be coupled to the channel plate 110 through a precision mounting system. The manifold 140 may comprise mechanical alignment features such as guide pins or alignment posts that mate with corresponding receptacles in the channel plate to ensure precise positioning of the passages 142 relative to the channels 112. The precision mounting system may comprise attachment points along the perimeter of the manifold 140, where securing mechanisms such as clamps, latches, or fasteners maintain consistent contact between the manifold 140 and the channel plate 110.

The precision mounting system may further comprise quick-release mechanisms or lever-actuated clamps to facilitate efficient engagement and disengagement of the manifold 140 from the channel plate 110. Control knobs or adjustment mechanisms may be used for fine-tuning of the contact pressure between the manifold 140 and the channel plate 110. In various embodiments, sensors may monitor the coupling status and sealing integrity during operation.

In various embodiments, the vacuum sources coupled to the vacuum lines 150 may comprise vacuum pumps such as mechanical pumps, turbo-molecular pumps, or combinations thereof for achieving desired vacuum levels. In some embodiments, multiple vacuum lines 150 may be independently controlled to create different pressure zones. The vacuum pumps coupled to the vacuum lines 150 may be applied to hold the polymer film 100 with the channel plate 110.

In one or more embodiments, the gas sources fluidly coupled to the gas flow lines 152 may comprise pressurized gas tanks storing process gases including nitrogen (N₂), oxygen (O₂), argon (Ar), compressed dry air, or combinations thereof. The gas tanks may be further coupled to a gas delivery system includes gas filters, pressure sensors, and flow meters to monitor and control gas distribution. Independent control valves enable selective activation of different gas flow lines 152 to create controlled gas pockets below specific regions of the wafer 102. Both vacuum and gas delivery systems incorporate safety interlocks and emergency shut-off mechanisms.

In various embodiments, a die chuck 104 may be configured to pick and place a first die 106 at a targeted position on the wafer 102. The first die 106 may be formed by singulating a large wafer into individual pieces and contain complete circuitry necessary for functioning as a standalone chip or component. The first die 106 may be square or rectangular shaped and comprise semiconductor materials such as silicon, gallium arsenide, silicon carbide, or the like. In some embodiments, the first die 106 may also be coated or layered with any number of additional materials, including compound semiconductors, metals, metal oxides, or metal nitrides, to meet specific functional requirements.

The die chuck 104 may be made from rigid materials such as stainless steel, aluminum, or ceramics such as alumina, zirconia, silicon carbide, or the like. In some embodiments, a vacuum system may be coupled to the die chuck 104 and configured to establish a vacuum zone between the die chuck 104 and the first die 106. The vacuum zone may enable the die chuck 104 to securely hold the first die 106 in place during bonding process. In alternative embodiments, the die chuck 104 may include electrostatic clamping capability through embedded electrodes to provide additional holding force.

In various embodiments, the die chuck 104 may maintain consistent alignment with the local protruding system 190, ensuring that the first die 106 may be aligned to the targeted bonding position. During operation, the die chuck 104 may move to pick up the first die 106 and return to align with the local protruding system 190 at a predetermined position. In one or more embodiments, the alignment of the die chuck 104 to the local protruding system 190 may repeat for each die pickup operation.

In an alternative embodiment, an alignment system may be coupled to the die chuck 104 and the local protruding system 190. The alignment system may comprise optical sensors and precision actuators configured to align the local protruding system 190 relative to the die chuck 104. The alignment system may detect and measure the relative positions of the local protruding system 190 and the die chuck 104, making automatic adjustments to achieve precise alignment. Once aligned, the local protruding system 190 and the die chuck 104 may be fixed at the aligned position for subsequent bonding operations.

In various embodiments, a striker mechanism may be integrated within the die chuck 104 or replace the die chuck 104 for applying bonding pressure. In some embodiments, the striker may be integrated within the die chuck 104. The striker may comprise an actuator that extends from the chuck body to provide controlled pressure after the die is positioned on the wafer. In one or more embodiments, the striker may include precision force control mechanisms such as pneumatic actuators, piezoelectric elements, or electromagnetic drives to generate adjustable bonding pressure.

In alternative embodiments, the striker may be a separate mechanism that replaces the die chuck 104 functionality. In one embodiment, the striker assembly may comprise both die handling capability and pressure application features. The striker assembly may comprise vacuum channels for securing the die during positioning, and an actuator system for applying controlled bonding force. In various embodiments, the striker may comprise force sensors and position feedback to monitor and adjust the applied pressure during the bonding process.

In various embodiments, the die chuck 104 may comprise alternative mechanisms for holding and releasing the first die 106 beyond vacuum-based pickup methods. In some embodiments, the die chuck 104 may use thermal release methods where adhesives or tapes may secure the first die 106 at room temperature but release when heated to increased temperature, for example, 80 °C to 200 °C, through integrated heating elements in the die chuck 104. In alternative embodiments, optical means such as infrared heating or laser systems may provide localized energy to change the adhesion between the first die 106 and the die chuck 104. In other embodiments, the die chuck 104 may use UV release methods by utilizing UV-sensitive adhesives over the first die 106. The UV-sensitive adhesives may lose adhesive strength when exposed to ultraviolet light (300-400 nm wavelength), thereby releasing the first die 106. In one or more embodiments, additional methods not specifically described herein, such as solvent-based release or electrostatic mechanisms may also be applied to achieve controlled die holding and release functionality. These alternative holding and release mechanisms accommodate various material constraints and process requirements, providing flexibility in die transfer operations depending on die properties, temperature sensitivity, and throughput considerations.

Referring back to FIG. 1B, in one or more embodiments, the local protruding system 190 may be positioned at a target bonding location beneath the wafer 102. A first channel 112 within the channel plate 110 may be aligned with a first passage 142 in the manifold 140, where the first passage 142 is coupled to the gas flow line 152. A second channel 112 in the channel plate 110 may be aligned with a second passage 142 in the manifold 140, where the second passage 142 is coupled to the vacuum line 150. In various embodiments, a gas from the gas tank may flow through the first passage 142 and the first channel 112 to form a gas pocket, or referred to below as a first gas pocket, beneath the polymer film 100, causing controlled local deformation of the polymer film 100 to create the locally protruding region 160 on the wafer 102. In various embodiments, the gas pressure may range from 1 to 100 psi and be actively controlled through pressure regulators and mass flow controllers. In one or more embodiments, the distribution of channels 112 carrying gas or vacuum may be selectively activated to tune the shape and height of the locally protruding region 160, until the surface topology of the locally protruding region 160 matches the footprint dimensions of the first die 106.

In FIG. 1C, the first die 106 and the wafer 102 form a temporary bond, following the alignment of the first die 106 above the locally protruding region 160. The die chuck 104 may place the first die 106 on the locally protruding region 160. The die chuck 104 may continue to apply pressure to the first die 106, minimizing the gap between the first die 106 and the wafer 102. This pressure may enhance van der Waals interactions at the interface between the wafer 102 and the first die 106, forming a stable temporary bonding. As the bond forms, the first die 106 may undergo scaling to alleviate stress, allowing it to conform precisely to the shape of the locally protruding region 160. This approach can compensate for the scaling of die during the bonding process, thereby improving alignment between wafer and die and enhancing overall device performance.

In one or more embodiments, the die chuck 104 may release pressure and retract vertically from the first die 106 after forming the temporary bond. In various embodiments, the gas pocket may be removed through a controlled evacuation process. In one embodiment, the first channel 112 and the first passage 142 may switch from coupling to the gas flow line 152 to the vacuum line 150 to remove the gas from the gas pocket. As the gas evacuates, the polymer film 100 and the wafer 102 may gradually return to their original planar configuration.

FIG. 1D illustrates bonding additional first dies 106 to the wafer 102 by repeating the process shown in FIGS. 1B and 1C. The local protruding system 190 may reposition to a new target location beneath the channel plate 110. In various embodiments, the manifold 140 aligns its passages 142 with corresponding channels 112 in the channel plate 110 at the new location. Gas may flow through selected passages 142 and channels 112 to create another gas pocket beneath the polymer film 100, forming a new locally protruding region on the wafer 102. The die chuck 104 may position an additional first die 106 above the new locally protruding region. In one or more embodiments, gas pressure and vacuum distribution through the passages 142 may be adjusted to tune the locally protruding region 160 to match the footprint of the additional first die 106. After bonding completion and gas pocket removal, the process repeats for subsequent first dies 106 until all desired locations on the wafer 102 are populated. In various embodiments, the polymer film 100 may maintain consistent wafer holding capability throughout multiple bonding cycles.

Referring to FIG. 1E, a final bonding process between the wafer 102 and the first dies 106 may be achieved by increasing the temperature of the wafer 102 in a separate processing chamber. In various embodiments, the wafer 102 and the first dies 106 may be separated from the polymer film 100 and the channel plate 110 and transferred to the separate processing chamber for final bonding. In some embodiments, the temperature may be maintained between 100 °C and 400 °C. The elevation in temperature may facilitate atomic diffusion at the interface between the wafer 102 and the first dies 106, forming covalent or ionic bonding that enhance bonding strength and improve device integrity. During this bake process, the van der Waals bond formed during the initial contact may be converted into permanent bond.

FIGS. 2A-2E illustrate an alternative die-to-wafer bonding process, in accordance with an embodiment. The process is different from the bonding process illustrated in FIGS. 1A-1E in applying a polymer film 200 comprising a plurality of through-holes 202 extending through the polymer film 200. Components and features in FIGS. 2A-2E that share reference numbers with those in FIGS. 1A-1E have corresponding structures and operations as previously described.

In FIG. 2A, the wafer 102 may be placed over the polymer film 200. In various embodiments, the polymer film 200 may comprise polymer materials including polyimide, polydimethylsiloxane (PDMS), polytetrafluoroethylene (PTFE), polyethylene terephthalate (PET), polycarbonate, or the like. The polymer film 200 may generate van der Waals forces between its surface and the wafer 102, providing sufficient adhesion to hold the wafer 102 in position during processing.

In various embodiments, the channel plate 110 may be coupled beneath the polymer film 200. The channels 112 within the channel plate 110 may be aligned with the through-holes 202 of the polymer film 200 to enable gas and vacuum delivery to selected regions below the wafer 102. In one or more embodiments, distributed vacuum zones may be created through a plurality of channels 112 across the channel plate 110, separate from those aligned with the extending portion 130 of the manifold 140. In some embodiments, these vacuum zones may form concentric rings or grid patterns around the perimeter of the channel plate 110, ensuring uniform contact between the polymer film 200, the wafer 102, and the channel plate 110 during the bonding process. In alternative embodiments, the channel plate 110 may comprise similar electrostatic chuck as described with reference to FIG. 1A. The electrostatic chuck may secure the wafer 102 through electrostatic forces generated by conductive electrodes embedded within the body of the channel plate 110.

In FIG. 2B, the local protruding system 190 may be positioned at the target bonding location beneath the wafer 102. In various embodiments, a first through-hole 202 within the polymer film 200 may be aligned with a first channel 112 within the channel plate 110, which may be aligned with a first passage 142 in the manifold 140. The first passage 142 may be coupled to the gas flow line 152. A second through-hole 202 within the polymer film 200 may be aligned with a second channel 112 within the channel plate 110, which may be aligned with a second passage 142 in the manifold 140. The second passage 142 may be coupled to the vacuum line 150. In various embodiments, a gas from the gas tank coupled to the gas flow line 152 may flow through the first passage 142, the first channel 112 and the first through-hole 202 to form a gas pocket beneath the wafer 102, creating a locally protruding region 260 on the wafer 102. In one or more embodiments, the pressure onto the wafer 102 from the gas pocket may be adjusted to tune the shape and height of the locally protruding region 260, until the surface topology of the locally protruding region 260 matches the footprint dimensions of the first die 106.

In FIG. 2C, a temporary bond between the first die 106 and the wafer 102 may be formed, following the process described with reference to FIG. 1C. After completing the formation of temporary bond, the first through-hole 202, the first channel 112 and the first passage 142 may switch from coupling to the gas flow line 152 to the vacuum line 150 to remove the gas from the gas pocket. As the gas evacuates, the wafer 102 may return to their original planar configuration.

FIG. 2D illustrates bonding additional first dies 106 to the wafer 102 by repeating the process shown in FIGS. 2B and 2C. The local protruding system 190 may reposition to a new target location beneath the channel plate 110. In various embodiments, the manifold 140 aligns its passages 142 with corresponding channels 112 in the channel plate 110 and through-holes 202 in the polymer film 200 at the new location. Gas may flow through selected passages 142, channels 112 and through-holes 202 to create another gas pocket beneath the wafer 102, forming a new locally protruding region 260 on the wafer 102. The die chuck 104 may position an additional first die 106 above the locally protruding region 160 to form a temporary bond with the wafer 102. After bonding completion and gas pocket removal, the process repeats for subsequent first dies 106 until all desired locations on the wafer 102 are populated.

In FIG. 2E, a final bonding process between the wafer 102 and the first dies 106 may be achieved by increasing the temperature of the wafer 102 in a separate processing chamber. In various embodiments, the wafer 102 and the first dies 106 may be separated from the polymer film 200 and the channel plate 110 and transferred to the separate processing chamber for final bonding. In some embodiments, the temperature may be maintained between 100 °C and 400 °C to facilitate atomic diffusion at the interface between the wafer 102 and the first dies 106, forming covalent or ionic bonding that enhance bonding strength and improve device integrity.

FIGS. 3A-3E illustrate yet another variation of die-to-wafer bonding process, in accordance with an embodiment. The process is different from previous bonding processes in directly coupling the wafer 102 to the channel plate 110 without a polymer film (e.g. the polymer films 100 and 200). Components and features in FIGS. 3A-3E that share reference numbers with those in FIGS. 1A-1E and 2A-2E have corresponding structures and operations as previously described.

FIG. 3A shows that the wafer 102 may be placed over the channel plate 110. In one or more embodiments, the channel plate 110 may securely hold the wafer 102 through the vacuum zones or electrostatic chuck as described with reference to 1A. In various embodiments, the surface of the channel plate 110 facing to the wafer 102 may be precisely polished to prevent wafer scratching and ensure proper sealing with the wafer 102. In some embodiments, the surface of the channel plate 110 facing to the wafer 102 may be coated with a layer of chemical-resistant material to enhance sealing properties and prevent surface degradation.

In FIG. 3B, the local protruding system 190 may be positioned at the target bonding location beneath the wafer 102. In various embodiments, a first channel 112 within the channel plate 110 may be aligned with a first passage 142 in the manifold 140. The first passage 142 may be coupled to the gas flow line 152. A second channel 112 within the channel plate 110 may be aligned with a second passage 142 in the manifold 140. The second passage 142 may be coupled to the vacuum line 150. In various embodiments, a gas from the gas tank coupled to the gas flow line 152 may flow through the first passage 142 and the first channel 112 to form a gas pocket between the wafer 102 and the channel plate 110, creating a locally protruding region 360 on the wafer 102. In one or more embodiments, the pressure onto the wafer 102 from the gas pocket may be adjusted to tune the shape and height of the locally protruding region 360, until the surface topology of the locally protruding region 360 matches the footprint dimensions of the first die 106.

In FIG. 3C, a temporary bond between the first die 106 and the wafer 102 may be formed, following the process described with reference to FIG. 1C. After completing the formation of temporary bond, the first channel 112 and the first passage 142 may switch from coupling to the gas flow line 152 to the vacuum line 150 to remove the gas from the gas pocket. As the gas evacuates, the wafer 102 may return to their original planar configuration.

FIG. 3D shows bonding additional first dies 106 to the wafer 102 by repeating the process shown in FIGS. 3B and 3C. The local protruding system 190 may reposition to a new target location beneath the channel plate 110. In various embodiments, the manifold 140 may align passages 142 with corresponding channels 112 in the channel plate 110 at the new target location. Gas may flow through selected passages 142 and channels 112 to create another gas pocket beneath the wafer 102, forming a new locally protruding region 360 on the wafer 102. The die chuck 104 may position an additional first die 106 above the locally protruding region 360 to form a temporary bond with the wafer 102. After bonding completion and gas pocket removal, the process repeats for subsequent first dies 106 until all desired locations on the wafer 102 are populated.

FIG. 3E shows a final bonding process between the wafer 102 and the first dies 106. In various embodiments, the wafer 102 and the first dies 106 may be separated from the channel plate 110 and transferred to a separate processing chamber for final bonding. In some embodiments, a temperature of the wafer 102 may be maintained between 100 °C and 400 °C to facilitate atomic diffusion at the interface between the wafer 102 and the first dies 106, forming covalent or ionic bonding that enhance bonding strength and improve device integrity.

Although not illustrated in FIGS. 1A-1E, 2A-2E, and 3A-3E, in various embodiments, while the manifold 140 may be coupled to specific channels 112 for creating the locally protruding region, other channels 112 across the channel plate 110 may be simultaneously coupled to additional vacuum sources. These additional channels 112, though not connected to the manifold 140, may provide distributed vacuum hold-down force across the wafer 102 or polymer film during the bonding process. The distributed vacuum hold through these additional channels 112 ensures stable positioning of the wafer 102 during manifold 140 movement and bonding operations. This dual-purpose vacuum distribution enhances process stability by maintaining consistent wafer or polymer film contact with the channel plate 110 while allowing independent control of the locally protruding region 160 through the manifold 140.

FIGS. 4A-4B illustrate a wafer singulation process following die-to-wafer bonding, in accordance with an embodiment. In various embodiments, the bonded wafer-die assembly may be separated from the polymer film 100 and channel plate 110 and transferred to a wafer singulation chamber.

FIG. 4A illustrates that the wafer 102 with bonded first dies 106 may be mounted on a supporting substrate 400 in the wafer singulation chamber. In various embodiments, the supporting substrate 400 may comprise a dicing tape with an adhesive layer mounted on a frame. The dicing tape may comprise UV-release adhesive films, thermal-release adhesive films, or pressure-sensitive adhesive films.

In one or more embodiments, the supporting substrate 400 may alternatively comprise a rigid carrier such as a glass substrate, silicon substrate, or ceramic plate. These rigid carriers may be temporarily bonded to the wafer 102 using mounting adhesives including wax, thermal release polymers, or temporary bonding adhesives. The mounting adhesives may withstand singulation processing temperatures and enable clean separation after dicing completion.

In FIG. 4B, the wafer 102 may be separated into individual semiconductor devices through singulation processes comprising mechanical sawing, laser cutting, or plasma etching. In an embodiment, a mechanical saw blade may cut along predetermined dicing streets between bonded regions. Alternatively, in another embodiment, a laser dicing process may utilize focused laser energy to remove material along singulation paths. In another embodiment, plasma etching processes may be applied to create separation trenches through masked etching steps. In various embodiments, cooling fluids or gases may circulate during dicing to control temperature and remove debris. After singulation, the individual devices undergo cleaning processes to remove any residual particles or processing materials.

FIGS. 5A-5D are schematic cross sectional views of a wafer singulation process after die stacking process, in accordance with an embodiment. Components and features in FIGS. 5A-5D that share reference numbers with those in FIGS. 1A-1E and FIGS. 4A-4B have corresponding structures and operations as previously described.

FIG. 5A illustrates a die stacking process where a second die 108 may be bonded to a previously positioned first die 106, prior to completing the final bonding process as illustrated in FIG. 1E, 2E or 3E. In alternative embodiments, the die stacking process illustrated in FIG. 5A may be performed after the final bonding process as illustrated in FIG. 1E, 2E or 3E. In various embodiments, while the local protruding system 190 maintains the gas pocket creating the protruding region 160 beneath the first die 106, the die chuck 104 may place the second die 108 on the first die 106 for die stacking. The manifold 140 may supply gas and vacuum through selected passages 142 and channels 112 to adjust the surface topology of locally protruding region 160, matching the footprint dimensions of the second die 108.

In one or more embodiments, after the second die 108 is temporarily bonded to the first die 106 below, the die chuck 104 may release pressure and retract vertically from the second die 108. In various embodiments, the gas pocket may be removed through a controlled evacuation process. Afterwards, the process may repeat for subsequent second dies 108 until all desired locations on the wafer 102 are populated.

Referring to FIG. 5B, a final bonding process may be performed. In various embodiments, the wafer 102 with temporarily bonded dies 106 and 108 may be separated from the polymer film 100 and the channel plate 110 and transferred to the separate processing chamber for final bonding. In some embodiments, the temperature may be maintained between 100 °C and 400 °C to facilitate atomic diffusion at interfaces between the wafer 102 and the first dies 106, and interfaces between the first dies 106 and the second dies 108. During this bake process, the van der Waals bonds formed during the initial contact may be converted into permanent bonds.

In various embodiments, while FIGS. 5A and 5B illustrate the die stacking process using the polymer film 100, similar stacking operations can be performed using alternative configurations. In some embodiments, the polymer film 100 may be replaced with the polymer film 200 having through-holes 202 aligned with the channels 112, as described in connection with FIGS. 2A-2E. In alternative embodiments, the stacking process may proceed without a polymer film, where the wafer 102 couples directly to the channel plate 110 as detailed in FIGS. 3A-3E. Each configuration enables multi-die stacking while maintaining appropriate gas pocket formation and pressure control through the manifold 140. The selection of polymer film configuration or direct wafer coupling depends on process requirements, temperature considerations, and desired deformation characteristics during the stacking operation.

FIG. 5C shows that the wafer 102 with bonded first dies 106 and second dies 108 may be transferred to wafer singulation chamber. In some embodiments, the wafer 102 may be mounted on the supporting substrate 400 for the singulation process.

FIG. 5D illustrates that the wafer 102 may be separated into individual semiconductor devices through the singulation process comprising the methods described with reference to the singulation process in FIG. 4B. In various embodiments, cooling fluids or gases may circulate during the singulation process to control temperature and remove debris. After singulating the wafer 102, the individual devices may undergo cleaning processes to remove any residual particles or processing materials.

Although FIGS. 4A, 4B, 5C and 5D illustrate separating the wafer 102 from the channel plate 110 and polymer film (the polymer films 100 or 200) for singulation, in some embodiments, such separation may not be required. The singulation process may be performed while the wafer 102 remains on the channel plate 110 or the polymer film. In one or more embodiments, the polymer film may provide sufficient support during dicing operations, eliminating the need for transfer to a separate supporting substrate such as a dicing tape. The channels 112 in the channel plate 110 may maintain vacuum hold during singulation to secure the wafer 102 and dies (e.g., the dies 106 and 108) in position. When singulating directly on the channel plate 110 or the polymer film, the cutting depth may be controlled to prevent damage to the underlying layers. This approach may reduce handling steps and potential alignment errors from additional transfers, while maintaining piece part stability throughout the singulation process.

FIG. 6A illustrates a bottom view of the channel plate 110 showing a plurality of channels 112 distributed across its surface. The plurality of channels 602 may appear as an array of holes on the channel plate 110 from the bottom view. In various embodiments, the channels 112 may be precision-machined openings with diameters ranging from 0.5 mm to 2 mm, arranged in a uniform grid pattern with center-to-center spacing of 2 to 5 mm.

FIG. 6B provides a detailed view of how the passages 142 within the extending portion 130 aligns with multiple channels 112, creating controlled zones for gas pocket formation and vacuum sealing. The spacing and arrangement of passages 142 may correspond precisely to the channel 112 grid pattern to ensure accurate alignment for consistent gas and vacuum delivery capability. In various embodiments, the channels 112 may be arranged in a uniform grid pattern, enabling the local protruding system 190 to create precisely controlled deformation regions on the wafer 102, including edge regions. This configuration supports various die sizes and enables flexible bonding patterns across the entire wafer surface.

FIGS. 7A and 7B illustrate an exemplary configuration of gas and vacuum distribution through the extending portion 130 of manifold 140. FIG. 7A shows a cross sectional view where passages 702 and 704 may be aligned to channels 112 in the channel plate 110. The passages 702 and 704 may be arranged in an alternating pattern within the manifold 140. FIG. 7B provides a bottom view revealing the arrangement of gas passages 702 and vacuum passages 704 within the manifold extending portion 130. In this configuration, the vacuum passages 704 may surround a central gas passage 702, creating a contained zone for gas pocket formation with peripheral vacuum sealing. In various embodiments, this concentric arrangement enables controlled local deformation while maintaining stability through the surrounding vacuum seal.

FIGS. 7C and 7D present another exemplary configuration of the gas and vacuum distribution pattern. In an embodiment, multiple gas passages 702 distribute across the manifold extending portion 130 with interspersed vacuum passages 704. This configuration may enable formation of more complex protruding region shapes or multiple gas pockets within a single bonding zone. In one or more embodiments, the distribution pattern of gas passages 702 and vacuum passages 704 may be customized to match specific die footprints or accommodate particular bonding requirements. The different configurations of gas and vacuum passage arrangements provide flexibility in controlling the shape, size, and stability of locally protruding regions. Independent control of each passage enables dynamic adjustment of pressure distribution during the bonding process.

Although FIGS. 6A, 6B, and 7A-7D illustrate the extending portion 130 comprising nine passages in a square arrangement, the configuration may vary in different embodiments. In some embodiments, the extending portion 130 may comprise fewer passages, such as four or six, for smaller die applications, or more than nine passages for larger dies or more complex pressure distribution patterns. In various embodiments, the extending portion 130 may be rectangular, circular, or other polygonal shapes to accommodate different die geometries. The number and arrangement of passages can be customized based on die size, required protruding region shape, and desired pressure control precision. This flexibility in design enables optimization for different die sizes, shapes, and bonding requirements.

FIG. 8 illustrates an alternative bonding process utilizing a carrier 850 that comprises a carrier local protruding system 890, a carrier channel plate 810, and a second polymer film 800. The carrier 850 may be also referred to below as the carrier 850. The second polymer film 800 may be also referred to below as the carrier polymer film 800. The carrier manifold 840 may comprise carrier passages 842 that are configured to be coupled to the gas sources through the gas flow lines 152 and vacuum sources through the vacuum lines 150. This configuration eliminates the need for the die chuck 104, enabling direct die transfer from the carrier 850 to the wafer 102. In various embodiments, the carrier polymer film 800 may provide enhanced stability for holding the dies 106 through van der Waals forces prior to bonding.

In various embodiments, the carrier 850 may comprise alternative mechanisms for holding and releasing the first die 106 beyond the gas pocket formation described above. In some embodiments, the carrier 850 may use thermal release methods where adhesives or tapes may secure the first die 106 at room temperature but release when heated to increased temperature, for example, 80 °C to 200 °C, through integrated heating elements in the carrier channel plate 810. In alternative embodiments, optical means such as infrared heating or laser systems may provide localized energy to change the adhesion between the first die 106 and the second polymer film 800 or the carrier channel plate 810. In other embodiments, the carrier 850 may use UV release methods by utilizing UV-sensitive adhesives over the first die 106. The UV-sensitive adhesives may lose adhesive strength when exposed to ultraviolet light (300-400 nm wavelength), thereby releasing the first die 106. The UV release methods may be enabled by UV-transparent sections or LED arrays in the carrier 850. In one or more embodiments, additional methods not specifically described herein, such as solvent-based release, electrostatic mechanisms, or mechanical approaches, may also be applied to achieve controlled die holding and release functionality. These alternative holding and release mechanisms accommodate various material constraints and process requirements, providing flexibility in die transfer operations depending on die properties, temperature sensitivity, and throughput considerations.

In various embodiments, the components of the carrier local protruding system 890 may comprise materials and features corresponding to those described in connection with the components of the local protruding system 190 in FIG. 1B. The carrier manifold 840 and the carrier channel plate 810 may be constructed of the same materials and include similar configurations as their corresponding components described in relation to FIG. 1B. The carrier polymer film 800 may comprise the same polymer materials and thickness ranges as the polymer film 100. The first die 106 may be held on a first side of the second polymer film 800 in the carrier 850.

During operation, the local protruding system 190 may create the first gas pocket beneath the polymer film 100 on the wafer side, forming a first locally protruding region 860 on the wafer 102 to match the footprint of the die 106. The carrier 850 may align and position the die 106 directly above the first locally protruding region 860. Simultaneously, the carrier local protruding system 890 may control gas and vacuum distribution through the carrier channel plate 810 to form a second gas pocket adjacent to an opposite second side of the second polymer film 800 to release the first die 106. The release process may transfer the first die 106 from the carrier 850 onto the first locally protruding region 860 on the wafer 102. The formation of the second gas pocket may apply a pressure to the first die 106 which may create a temporary bond between the first die 106 and the wafer 102.

In one or more embodiments, after initial die placement, the carrier 850 may reposition to align additional dies 106 with new target locations on the wafer 102. The local protruding system 190 may create successive gas pockets at each new location, enabling sequential die bonding across the wafer surface. This process may repeat until all dies 106 transfer from the carrier 850 to their designated positions on the wafer 102.

The carrier 850 may streamline the bonding process by eliminating separate pick-and-place operations, reducing handling steps and potential alignment errors. The system may provide precise control of die release and placement through coordinated operation of gas and vacuum distribution in both the wafer and carrier portions of the assembly.

FIG. 9 illustrates yet another bonding process that enables simultaneous bonding of multiple dies, enhancing process efficiency, in accordance with an embodiment. The carrier 850 may comprise multiple carrier local protruding systems 890 positioned to hold multiple dies (e.g., the first and second dies 106 and 108) concurrently. Each carrier local protruding system 890 may include its own carrier manifold 840 with carrier passages 842 coupled to the gas flow lines 152 and the vacuum lines 150 through the connectors 144. Components and features in FIG. 9 that share reference numbers with those in FIGS. 1A-1E and FIG. 8 may have corresponding structures and operations as previously described.

In various embodiments, the carrier channel plate 810 may extend across multiple die positions, with the carrier polymer film 800 providing consistent die holding capability through van der Waals forces across its surface. The multiple carrier local protruding systems 890 may operate independently, enabling simultaneous control of gas and vacuum distribution for multiple dies. Correspondingly, multiple local protruding systems 190 beneath the wafer 102 may create concurrent locally protruding regions on the wafer 102 to match footprints of the dies.

During operation, the local protruding systems 190 may create multiple gas pockets beneath the polymer film 100. As shown in FIG. 9, the first die 106 and the second die 108 may be held on the first side of the carrier polymer film 800 in the carrier 850 through van der Waals forces. In an embodiment, the local protruding system 190 may form a first gas pocket beneath the polymer film 100 to create a first locally protruding region 960. The carrier local protruding systems 890 may form a corresponding second gas pocket adjacent to the opposite second side of the carrier polymer film 800 to release the first die 106. Simultaneously, the local protruding system 190 may form a third gas pocket beneath the polymer film 100 to create a second locally protruding region 965. The carrier local protruding systems 890 may form a corresponding fourth gas pocket adjacent to the opposite second side of the carrier polymer film 800 to release the second die 108. The carrier 850 may enable parallel transfer of multiple dies directly from the carrier onto their corresponding regions on the wafer 102. Each manifold 140 and carrier manifold 840 may independently control its gas and vacuum distribution through passages 142 and 842 respectively to coordinate the formation of protruding regions and die release. This parallel processing capability may significantly reduce bonding cycle time compared to sequential pick-and-place operations.

In various embodiments, the parallel bonding process may repeat to stack additional die layers. After the first and second dies 106 and 108 are bonded, the carrier 850 may hold and transfer an additional layer of dies simultaneously onto the bonded dies (e.g., the first and second dies 106 and 108). The local protruding systems 190 may create multiple gas pockets beneath the polymer film 100 to form protruding regions on the bonded dies, while the carrier local protruding systems 890 coordinate gas pocket formation through carrier passages 842 to release the additional layer of dies. Each subsequent die layer may be parallel bonded following the same process, where multiple dies transfer simultaneously from the carrier 850 to their corresponding positions on the previously bonded die layer. This parallel stacking capability enables efficient formation of complex three-dimensional integrated circuits with multiple die layers while maintaining the throughput advantages of simultaneous die transfer compared to sequential stacking approaches.

In various embodiments, while FIGS. 8 and 9 illustrate usage of the polymer film 800, alternative configurations may employ a polymer film with through-holes similar to polymer film 200, or operate without a polymer film where wafer is coupled directly to the channel plate 110. The carrier polymer film 800 or the first die 106 may be secured to the carrier channel plate 810 through distributed vacuum zones or electrostatic chuck designs as described previously with reference to FIG. 1A. In one or more embodiments, vacuum zones formed by channels in the carrier channel plate 810 may create concentric rings or grid patterns around the perimeter of the carrier channel plate 810 that apply holding force to maintain the carrier polymer film 800 or the first die 106 in position. In alternative embodiments, the carrier channel plate 810 may function as an electrostatic chuck to hold the first die 106.

In various embodiments, the die (e.g., the first dies 106 and the second dies 108) and wafer (e.g., the wafer 102) may undergo cleaning processes prior to bonding to ensure optimal surface conditions. The wafer surface may receive a combination of wet cleaning steps including solvent rinse, deionized water wash, and acid or base treatments to remove organic contaminants, particles, and surface oxides. In one or more embodiments, the die surfaces may undergo similar wet cleaning sequences followed by precision drying to prevent watermark formation. Additional surface treatments may include plasma cleaning, UV-ozone exposure, or reactive gas treatments to activate bonding surfaces and remove molecular contamination. The cleaning processes may be performed in dedicated cleaning chambers integrated with the bonding system. In various embodiments, surface inspection tools may verify cleanliness levels before die placement, and environmental controls within the bonding chamber maintain clean conditions during the bonding process. The cleaned surfaces enable direct molecular bonding between the die and wafer at the locally protruding region without intermediate layers.

Example embodiments of the invention are described below. Other embodiments can also be understood from the entirety of the specification as well as the claims filed herein.
Example 1. An apparatus for die-to-wafer bonding, the apparatus including: a channel plate configured to hold a wafer and create a locally protruding region on the wafer; a manifold including a plurality of passages and configured to be coupled to the channel plate; a first channel within the channel plate, the first channel configured to be aligned with a first passage within the manifold, where the first passage is configured to be coupled to a gas flow line; and a second channel within the channel plate, the second channel configured to be aligned with a second passage within the manifold, where the second passage is configured to be coupled to a vacuum line.
Example 2. The apparatus of example 1, further including a die chuck configured to pick up a die and move to align with the wafer.
Example 3. The apparatus of one of examples 1 or 2, further including a vacuum source coupled to the channel plate, the vacuum source configured to create vacuum zones around a perimeter of the channel plate to secure the wafer to the channel plate.
Example 4. The apparatus of one of examples 1 to 3, where the channel plate includes an electrostatic chuck configured to secure the wafer to the channel plate.
Example 5. The apparatus of one of examples 1 to 4, further including a polymer film disposed over the channel plate.
Example 6. The apparatus of one of examples 1 to 5, where the polymer film includes a plurality of through-holes extending through the polymer film, and where a first through-hole is aligned with the first channel of the channel plate.
Example 7. The apparatus of one of examples 1 to 6, where the polymer film includes polyimide, polydimethylsiloxane (PDMS), polytetrafluoroethylene (PTFE), polyethylene terephthalate (PET), or polycarbonate.
Example 8. A method for die-to-wafer bonding, the method including: placing a wafer over a channel plate; forming a gas pocket between the channel plate and the wafer to form a first locally protruding region on the wafer; placing a first die on the first locally protruding region on the wafer; and bonding the first die to the wafer at the first locally protruding region.
Example 9. The method of example 8, where a top surface of the first locally protruding region facing the first die corresponds to a footprint of the first die.
Example 10. The method of one of examples 8 or 9, further including singulating the wafer into individual dies after bonding the first die to the wafer.
Example 11. The method of one of examples 8 to 10, further including: placing a second die on the first die; and bonding the second die to the first die.
Example 12. The method of one of examples 8 to 11, further including singulating the wafer into individual dies after bonding the second die to the first die.
Example 13. The method of one of examples 8 to 12, further including: disposing a first polymer film over the channel plate; and placing the wafer over the first polymer film.
Example 14. The method of one of examples 8 to 13, where placing the first die on the first locally protruding region of the wafer includes: holding the first die on a first side of a second polymer film in a carrier; forming a second gas pocket adjacent to an opposite second side of the second polymer film to release the first die; and transferring the first die from the carrier onto the first locally protruding region on the wafer.
Example 15. The method of one of examples 8 to 14, further including: holding a second die on the first side of the second polymer film in the carrier; forming a third gas pocket adjacent to the opposite second side of the first polymer film to form a second locally protruding region on the wafer; forming a fourth gas pocket adjacent to the opposite second side of the second polymer film to release the second die; and transferring the first die and the second die simultaneously from the carrier onto the first locally protruding region and the second locally protruding region on the wafer.
Example 16. A method for die-to-wafer bonding, the method including: placing a wafer over a channel plate, the channel plate being coupled to a manifold including a plurality of passages; aligning a first passage within the manifold to a first channel within the channel plate, where the first passage is coupled to a gas flow line; supplying gas through the first passage and the first channel to form a gas pocket between the wafer and the channel plate, where the gas pocket deforms the wafer to form a locally protruding region; and bonding a first die to the wafer at the locally protruding region.
Example 17. The method of example 16, further including: aligning a second passage within the manifold to a second channel within the channel plate, where the second passage is coupled to a vacuum line, and where a vacuum through the second passage and the second channel holds the wafer to the channel plate.
Example 18. The method of one of examples 16 or 17, further including: applying pressure to the first die using a striker to place the first die on the locally protruding region of the wafer.
Example 19. The method of one of examples 16 to 18, further including singulating the wafer into individual dies after bonding the first die to the wafer.
Example 20. The method of one of examples 16 to 19, further including: bonding a second die to the first die; and singulating the wafer into individual dies after bonding the second die to the first die.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-9 may be combined in further embodiments. It is therefore intended that the appended claims encompass any such modifications or embodiments.

What is claimed is:

1. An apparatus for die-to-wafer bonding, the apparatus comprising:
a channel plate configured to hold a wafer and create a locally protruding region on the wafer;
a manifold comprising a plurality of passages and configured to be coupled to the channel plate;
a first channel within the channel plate, the first channel configured to be aligned with a first passage within the manifold, wherein the first passage is configured to be coupled to a gas flow line; and
a second channel within the channel plate, the second channel configured to be aligned with a second passage within the manifold, wherein the second passage is configured to be coupled to a vacuum line.

2. The apparatus of claim 1, further comprising a die chuck configured to pick up a die and move to align with the wafer.

3. The apparatus of claim 1, further comprising a vacuum source coupled to the channel plate, the vacuum source configured to create vacuum zones around a perimeter of the channel plate to secure the wafer to the channel plate.

4. The apparatus of claim 1, wherein the channel plate comprises an electrostatic chuck configured to secure the wafer to the channel plate.

5. The apparatus of claim 1, further comprising a polymer film disposed over the channel plate.

6. The apparatus of claim 5, wherein the polymer film comprises a plurality of through-holes extending through the polymer film, and wherein a first through-hole is aligned with the first channel of the channel plate.

7. The apparatus of claim 5, wherein the polymer film comprises polyimide, polydimethylsiloxane (PDMS), polytetrafluoroethylene (PTFE), polyethylene terephthalate (PET), or polycarbonate.

8. A method for die-to-wafer bonding, the method comprising:
placing a wafer over a channel plate;
forming a gas pocket between the channel plate and the wafer to form a first locally protruding region on the wafer;
placing a first die on the first locally protruding region on the wafer; and
bonding the first die to the wafer at the first locally protruding region.

9. The method of claim 8, wherein a top surface of the first locally protruding region facing the first die corresponds to a footprint of the first die.

10. The method of claim 8, further comprising singulating the wafer into individual dies after bonding the first die to the wafer.

11. The method of claim 8, further comprising:
placing a second die on the first die; and
bonding the second die to the first die.

12. The method of claim 11, further comprising singulating the wafer into individual dies after bonding the second die to the first die.

13. The method of claim 8, further comprising:
disposing a first polymer film over the channel plate; and
placing the wafer over the first polymer film.

14. The method of claim 13, wherein placing the first die on the first locally protruding region of the wafer comprises:
holding the first die on a first side of a second polymer film in a carrier;
forming a second gas pocket adjacent to an opposite second side of the second polymer film to release the first die; and
transferring the first die from the carrier onto the first locally protruding region on the wafer.

15. The method of claim 14, further comprising:
holding a second die on the first side of the second polymer film in the carrier;
forming a third gas pocket adjacent to the opposite second side of the first polymer film to form a second locally protruding region on the wafer;
forming a fourth gas pocket adjacent to the opposite second side of the second polymer film to release the second die; and
transferring the first die and the second die simultaneously from the carrier onto the first locally protruding region and the second locally protruding region on the wafer.

16. A method for die-to-wafer bonding, the method comprising:
placing a wafer over a channel plate, the channel plate being coupled to a manifold comprising a plurality of passages;
aligning a first passage within the manifold to a first channel within the channel plate, wherein the first passage is coupled to a gas flow line;
supplying gas through the first passage and the first channel to form a gas pocket between the wafer and the channel plate, wherein the gas pocket deforms the wafer to form a locally protruding region; and
bonding a first die to the wafer at the locally protruding region.

17. The method of claim 16, further comprising:
aligning a second passage within the manifold to a second channel within the channel plate, wherein the second passage is coupled to a vacuum line, and wherein a vacuum through the second passage and the second channel holds the wafer to the channel plate.

18. The method of claim 16, further comprising:
applying pressure to the first die using a striker to place the first die on the locally protruding region of the wafer.

19. The method of claim 16, further comprising singulating the wafer into individual dies after bonding the first die to the wafer.

20. The method of claim 16, further comprising:
bonding a second die to the first die; and
singulating the wafer into individual dies after bonding the second die to the first die.
